(19) United States
(12) Patent Application Publication
(10) Pub. No.: US 2024/0113091 A1
(43) Pub. Date: Apr. 4, 2024

(54) PACKAGE WITH SEMICONDUCTOR STRUCTURE AND METHOD FOR MANUFACTURING THE SAME

(71) Applicant: TAIWAN SEMICONDUCTOR MANUFACTURING COMPANY LTD., HSINCHU (TW)

(72) Inventors: WEN-SHUN LO, HSINCHU COUNTY (TW); JING-HWANG YANG, HSINCHU COUNTY (TW); YINGKIT FELIX TSUI, CUPERTINO, CA (US)

(21) Appl. No.: 18/155,076

(22) Filed: Jan. 17, 2023

Related U.S. Application Data
(60) Provisional application No. 63/378,075, filed on Oct. 2, 2022.

(51) Int. Cl. H01L 25/16; G02B 6/42; H01L 23/48; H01L 23/498; H01L 23/522; H01L 23/538

(52) U.S. Cl. CPC H01L 25/167; G02B 6/4214; H01L 23/481; H01L 23/49816; H01L 23/5226; H01L 23/538; H01L 24/08; H01L 2224/08145

(57) ABSTRACT

The present disclosure provides a package with a semiconductor structure and a method for manufacturing the semiconductor structure. In some embodiments, a photonic semiconductor structure includes a substrate having a first side and a second side opposite to each other, a first redistribution layer disposed on the first side, an interconnect structure disposed on the second side of the substrate, a metal reflector disposed in the interconnect structure, a dielectric layer disposed over the interconnect structure, and a grating coupler disposed in the dielectric layer and overlapping the metal reflector.

### PRIORITY CLAIM AND CROSS-REFERENCE

This application claims the benefit of prior-filed provisional application No. 63/378,075, filed on Oct. 2, 2022.

### BACKGROUND

The semiconductor integrated circuit (IC) industry has experienced rapid growth. Technological advances in IC materials and design have produced continuous improvements in generations of ICs. Each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased.

However, as the feature sizes continue to decrease, fabrication processes continue to become more difficult to perform. Thus, there is a challenge to form high efficiency semiconductor ICs with smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a cross-sectional view of a photonic die (photonic integrated circuit, PIC) according to some embodiments of the present disclosure.

FIG. 2 illustrates a cross-sectional view of a semiconductor package according to some embodiments of the present disclosure.

FIG. 3 illustrates an example flow chart of a method for making a photonic die according to some embodiments of the present disclosure.

FIGS. 4A-4N illustrate respective cross-sectional views of the semiconductor package during various fabrication stages according to some embodiments of the present disclosure.

FIG. 5 illustrates an example exploded view of a semiconductor package according to some embodiments of the present disclosure.

FIG. 6 illustrates an example cross-sectional view of the semiconductor package according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In the present disclosure, a phrase “one of A, B and C” means “A, B and/or C” (A, B, C, A and B, A and C, B and C, or A, B and C), and does not mean one element from A, one element from B and one element from C, unless otherwise described.

As used herein, although terms such as “first,” “second” and “third” describe various elements, components, regions, layers and/or sections, these elements, components, regions, layers and/or sections are not limited by these terms. These terms are used to distinguish one element, component, region, layer, or section from another. Terms such as “first,” “second” and “third” in response to used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that is contemplated by people having ordinary skill in the art. Alternatively, the terms “substantially,” “approximately” and “about” mean within an acceptable standard error of the mean in response to considered by one of ordinary skill in the art. People having ordinary skill in the art understand that the acceptable standard error varies according to different technologies. Other than in the operating/working examples, or unless otherwise expressly specified, the numerical ranges, amounts, values, and percentages such as those for quantities of materials, durations of times, temperatures, operating conditions, ratios of amounts, and the likes thereof disclosed herein should be understood as modified in instances by the terms “substantially,” “approximately” or “about.” Accordingly, unless indicated to the contrary, the numerical parameters set forth in the present disclosure and attached claims are approximations that vary as desired. At the very least, each numerical parameter is construed considering the number of reported significant digits and by applying ordinary rounding techniques. Ranges are expressed herein as from one endpoint to another endpoint or between two endpoints. All ranges disclosed herein are inclusive of the endpoints, unless otherwise specified.

An optical device (e.g., a PIC) provides a better way to provide high bandwidth, low latency, high energy-efficiency, high speed, data communication, e.g., in the areas of data center, 5G (5th generation mobile networks), and AI (artificial intelligence) electronic systems. In some comparative approaches, a grating coupler (GC) is a way to transfer light from an optical fiber to a photonics IC, and from the photonic IC to the optical fiber during development and production stages. A coupling efficiency of the GC (>1.0 dB) is usually lower than a coupling efficiency (<1.0 dB) of an edge coupler (EC). Although the coupling efficiency of the edge coupler is better, the coupling efficiency may only be measured until the wafer is diced. This is not convenient and may cause more consumption. However, the GC may lose about 40% to 60% of the light from the optical fiber. Thus, there is a need to enhance the coupling efficiency of the GC. By combining a mirror (or a reflector) to the GC, the coupling efficiency of the GC may be optimized to about 0.5 dB, which is better than the coupling efficiency of the EC. By using the GC with the reflector, the light may be reflected back to the GC by the reflector. In this way, the GC coupling efficiency can be enhanced by reducing the light loss.

To develop an effective, low cost, and production-friendly, a high efficiency photonics IC and a method to combine a grating coupler and a reflector is therefore provided. The present disclosure provides various embodiments of a semiconductor package including an optical device (e.g., PIC referred as photonic die herein) which may be electrically coupled to an electrical device (e.g., electronic integrated circuit (EIC) referred as electronic die herein), a processor die, an optical fiber, a package substrate, or other devices.

In some embodiments, a semiconductor package may be formed as a (e.g., three-dimensional (3D)) semiconductor package, for example, formed on a common package substrate. Numbers of semiconductor packages may be interconnected by an optical pathway, which allows the separate semiconductor packages to communicate with each other. For example, the optical pathway may be a closed loop (or ring) that connects to each semiconductor package. As such, each semiconductor package may communicate with other semiconductor package via the optical pathway.

In some embodiments, each semiconductor package may include a processor die, an electronic die (an implementation of the electrical device), a photonic die (an implementation of the optical device), and an optical fiber. The optical pathway extends between one or more components of each semiconductor package, for example, extends between the photonic die of each semiconductor package. The processor die may be a central processing unit (CPU), graphics processing unit (GPU), application-specific integrated circuit (ASIC), field programmable array (FPGA), or the like. The photonic die can transmit, receive, convert, modulate, demodulate, or otherwise process optical signals. For example, the photonic die can convert electrical signals from the processor die to optical signals, and convert optical signals to electrical signals. The photonic die can communicate such optical signals through the optical pathway with one or more other photonic dies. The photonic die can receive the optical signals from the optical fiber, and transmit and/or receive the optical signals via one or more waveguides of the optical pathway. Accordingly, the photonic die is responsible for the input/output (I/O) of optical signals to/from the optical pathway.

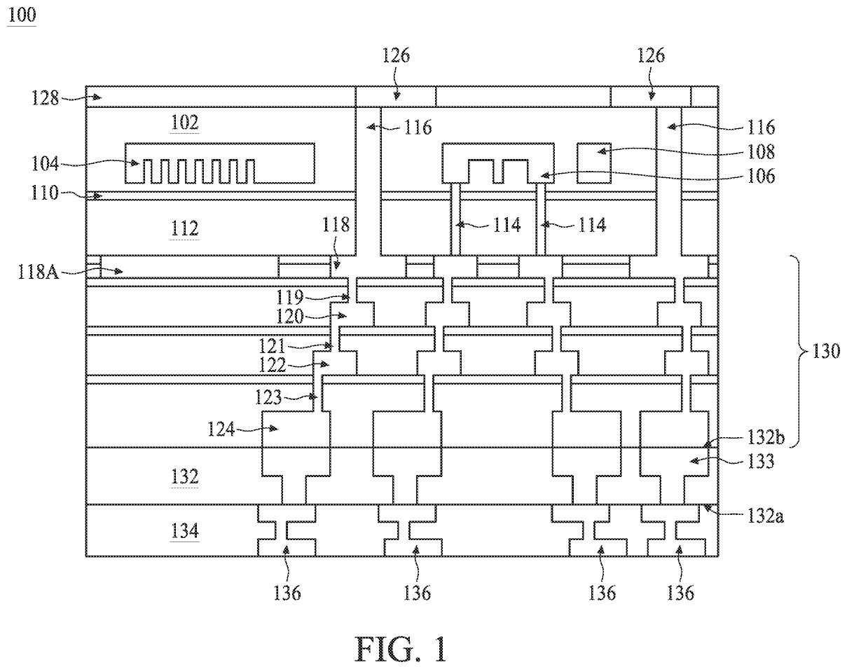

FIG. 1 illustrates a cross-sectional view of a photonic die 100 according to some embodiments of the present disclosure. In some embodiments, the photonic die 100 is a PIC. In some embodiments, a photonic die 100 includes a substrate 132 with a first side 132a and a second side 132b opposite to each other, a first redistribution layer 134 (including first redistribution lines 136) disposed on the first side 132a, an interconnect structure 130 disposed on the second side 132b of the substrate 132, a metal reflector 118A disposed in the interconnect structure 130, a dielectric layer 112 disposed over the interconnect structure 130, an insulating layer 102 disposed over the dielectric layer 112, and a grating coupler 104 disposed in the insulating layer 102 and overlapping the metal reflector 118A. In some embodiments, a thickness of the photonic die 100 is with a range from about 100 micrometers (μm) to about 400 μm, but the disclosure is not limited thereto.

In some embodiments, the substrate 132 is a carrier wafer bonded with the PIC by direct bonding (for example, Cu-to-Cu and Ox-to-Ox). In some embodiments, the carrier wafer is commonly used in a wafer-on-wafer (WOW) semiconductor package. In some embodiments, the carrier wafer may have one or more through-substrate vias (TSVs) formed through the carrier wafer. In some embodiments, a thickness of the carrier wafer is with a range from about 100 μm to about 400 μm, but the disclosure is not limited thereto. The wafer carrier comprises, for example, silicon based materials, such as glass or silicon oxide, or other materials, such as aluminum oxide, combinations of any of these materials, or the like. The wafer carrier is planar in order to accommodate its attachment to the semiconductor wafer. In some embodiments, the photonic die 100 further includes a plurality of connecting structures 133 disposed in the substrate 132 and electrically coupling the first redistribution layer 134 to the interconnect structure 130.

Referring to the FIG. 1, in some embodiments, the interconnect structure 130 further includes a plurality of metallization layers 118, 120, 122 and 124 and a plurality of inter-level via connectors 119, 121 and 123. In some embodiments, the plurality of metallization layers 118, 120, 122 and 124 and the plurality of inter-level via connectors 119, 121 and 123 are embedded in the dielectric layer 112. In some embodiments, the metallization layers 118, 120, 122 and 124 and the inter-level via connectors 119, 121 and 123 are comprised of metallic material such as copper, aluminum, or alloys thereof, using known techniques such as damascene, dual damascene, or subtractive metal etching. Although the exemplary embodiments described herein depict five metal layers, this is merely illustrative and it should be understood that the photonic die 100 may alternatively be formed with more or fewer metal layers, depending on the application. The plurality of inter-level via connectors 119, 121 and 123 provide interconnections between the metallization layers 118, 120, 122 and 124.

In some embodiments, the metal reflector 118A may be disposed at one of layers of the plurality of metallization layers 118, 120, 122 and 124. In some embodiments, the metal reflector 118A may be disposed at a topmost metallization layer 118 of the plurality of metallization layers 118, 120, 122 and 124. In some embodiments, the metal reflector 118A may be formed during the same process of forming one of the plurality of metallization layers 118, 120, 122 and 124. There is no extra process for forming the metal reflector 118A. In some embodiments, the metal reflector 118A is disposed in the interconnect structure 130, and electrically separated from the metallization layers 118, 120, 122 and 124. In some embodiments, a cross-sectional length of the metal reflector 118A is larger than a cross-sectional length of the grating coupler 104, for example, larger than about 1 μm.

In some embodiments, the dielectric layer 112 may be a plurality of layers of ILD (inter level dielectric, also known as pre-metal dielectric) material. In some embodiments, the ILD material includes multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. In some embodiments, the ILD material may be formed by chemical vapor deposition (CVD), physical vapor deposition (PVD), atomic layer deposition (ALD), spin-on coating, or other applicable processes.

In some embodiments, the photonic die 100 further includes a contact etch stop layer (CESL) 110 disposed over the dielectric layer 112. In some embodiments, the CESL 110 may include a dielectric material, such as, silicon nitride, silicon oxide, silicon oxynitride, or the like. In some embodiments, the CESL 110 is blanket deposited by Plasma-Enhanced Chemical Vapor Deposition (PECVD), or other methods such as ALD or Low Pressure Chemical Vapor Deposition (LPCVD).

In some embodiments, the insulating layer 102 disposed over the CESL 110 may be comprised of any suitable material, including silicon oxide, sapphire, other suitable insulating materials, and/or combinations thereof. An exemplary insulator layer may be a buried oxide layer (BOX). The insulator may be formed by any suitable process, such as implantation (e.g., SIMOX), oxidation, deposition, and/or other suitable process.

In some embodiments, the grating coupler 104 transmits light to or receive light from the overlying light source or optical signal source of the optical fiber. The grating coupler 104 may be formed by photolithography and etching techniques. In some embodiments, the grating coupler 104 includes one of a metal, such as copper or aluminum, or a high-k dielectric material. In some embodiments, the grating pitch of the grating coupler 104 is greater than the critical dimension (CD) of the process, but the disclosure is not limited thereto. In some embodiments, the grating coupler 104 has different grating periods defined by different grating pitch.

Still referring to FIG. 1, in some embodiments, the photonic die 100 further includes a modulator 106 disposed in the insulating layer 102, a strip 108 disposed in the insulating layer 102, and a connecting structure 114 penetrating the dielectric layer 112 and electrically coupling one of the metallization layers 118, 120, 122 and 124 of the interconnect structure 130 with the modulator 106. In some embodiments, the modulator 106 is disposed adjacent to the grating coupler 104. In some embodiments, a material of the modulator 106 is silicon, SiON, or other suitable material. In some embodiments, the light from the optical fiber may be reflected back to the grating coupler 104 by the metal reflector 118A. Further, the grating coupler 104 delivers light to the modulator 106 and receives light from the modulator 106 back to the optical fiber. In this way, the efficiency of the modulator 106 can be enhanced as well as the grating coupler 104 by the metal reflector 118A. As a result, the metal reflector 118A also helps enhancing the efficiency of the modulator 106. In some embodiments, the strip 108 is disposed adjacent to the modulator 106.

In some embodiments, the connecting structure 114 electrically couples the modulator 106 and the interconnect structure 130. In some embodiments, the grating coupler 104 delivers light to the modulator 106, and the modulator 106 transforms the light signal into modulated light signal to the interconnect structure 130 via the connecting structure 114. The connecting structure 114 may be formed of standard materials such as copper or tungsten.

In some embodiments, the photonic die 100 further includes a second RDL layer 128 (including second RDL lines 126) disposed over the dielectric layer 112 and the insulating layer 102. At least one through substrate via 116 penetrates the insulating layer 102 and the dielectric layer 112, and electrically couples one of the metallization layers 118, 120, 122 and 124 of the interconnect structure 130 with the second RDL lines 126.

As described above, the metal reflector 118A reflects the light from the optical fiber back to the grating coupler 104 as to enhance the coupling efficiency of the grating coupler 104. No extra process need to be performed to form the metal reflector 118A. The improvement of the coupling efficiency may also increase the efficiency of photonic die 100.

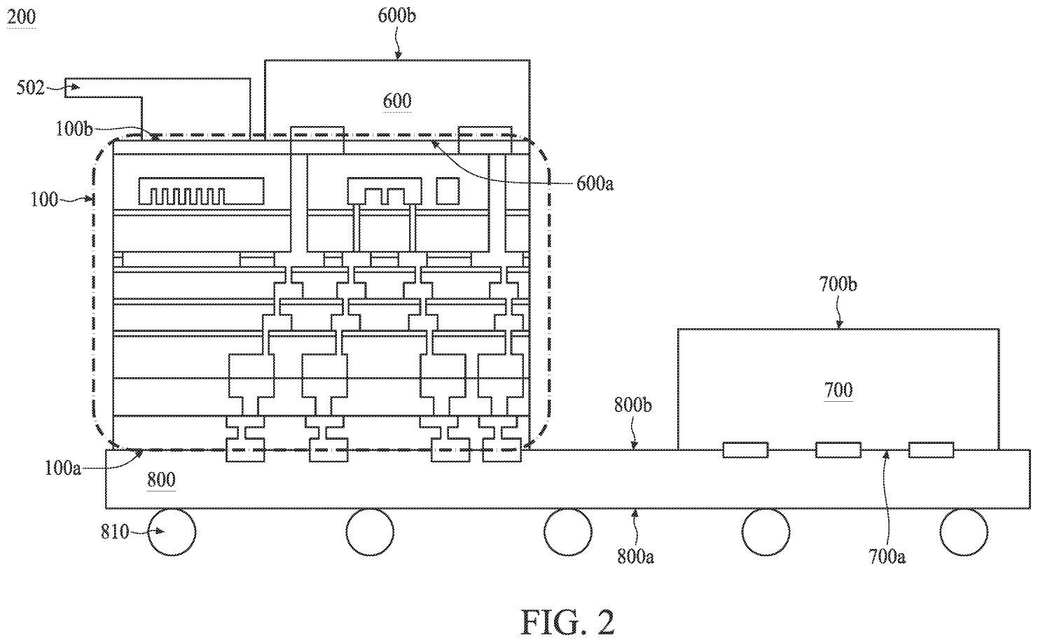

FIG. 2 illustrates a cross-sectional view of a semiconductor package 200 according to some embodiments of the present disclosure. In some embodiments, the semiconductor package 200 may be formed as a 3D semiconductor package, for example, formed on a common package substrate 800. In some embodiments, the package substrate 800 includes a first side 800a and a second side 800b opposite to the first side 800a. In some embodiments, the package substrate 800 may be an interposer formed of, for example, silicon. In some embodiments, a plurality of conductors 810 disposed on the first side 800a of the package substrate 800. In some embodiments, the plurality of conductors 810 may be bumps, micro bumps (μbump), or balls made of a solder material, but the disclosure is not limited thereto.

In some embodiments, the photonic die 100 is disposed over the second side 800b of the package substrate 800 and electrically coupled to the package substrate 800. In some embodiments, the photonic die 100 includes a first side 100a and a second side 100b opposite to the first side 100a. The details of the photonic die 100 has been discussed in FIG. 1; therefore, some details are omitted. In some embodiments, a bonding between the photonic die 100 and the package substrate 800 maybe a direct bonding or micro-bump (chip to wafer bonding).

In some embodiments, an electrical die 600 is disposed over the photonic die 100 and electrically connected to the photonic die 100. In some embodiments, the electrical die 600 includes a first side 600a and a second side 600b opposite to the first side 600a. In some embodiments, a bonding between the photonic die 100 and the electrical die 600 maybe a direct bonding or micro-bump (chip to chip bonding). The first side 600a of the electrical die 600 is facing the second side 100b of the photonic die 100.

In some embodiments, the semiconductor package 200 further includes an optical fiber 502 disposed over and coupled to the photonic die 100. In some embodiments, the optical fiber 502 overlaps the grating coupler 104 of the photonic die 100. In some embodiments, the optical fiber 502 and the electrical die 600 are disposed over a same surface of the photonic die 100. In some embodiments, the metal reflector 118A of the interconnect structure 130 shown in FIG. 1 can reflect the light between the optical fiber 502 and the grating coupler 104.

In some embodiments, the semiconductor package 200 further includes a processor die 700 disposed over the second side 800b of the package substrate 800 and electrically coupled to the package substrate 800. In some embodiments, the processor die 700 is separated from the photonic die 100, as shown in FIG. 2, but the disclosure is not limited thereto. A thickness of the processor die 700 may be less than a thickness of the photonic die 100, but the disclosure is not limited thereto. As mentioned above, the processor die 700 may be a CPU, GPU, ASIC, FPGA, or the like. In this way, the photonic die 100 can convert electrical signals from the processor die 700 to optical signals, and convert optical signals to electrical signals, and transit the electrical signals to the electrical die 600. The photonic die 100 can receive the optical signals from the optical fiber 502, and transmit and/or receive the optical signals via one or more waveguides. Accordingly, the photonic die 100 is responsible for the input/output (I/O) of optical signals to/from the optical fiber 502. With the metal reflector 118A underlying the grating coupler 104 of the photonic die 100, the photonic die 100 can have a significantly improved light coupling efficiency. Light coupling efficiency may be enhanced by the metal reflector 118A to reflect the light and constructively interfere with the light coupled between the optical fiber 502 and the grating coupler 104.

In some embodiments, the electrical die 600 electrically connects the photonic die 100 via the second RDL lines 126. As such, electrical signals may be transmitted between the photonic die 100 and the electrical die 600, so that the electrical signals between the photonic die 100 and the electrical die 600 can be exchanged. In some embodiments, the package substrate 800 is electrically coupled with the photonic die 100 and a processor die 700, so that the electrical signals can be communicated through the photonic die 100, the electrical die 600, and the processor die 700. As such, an electrical transmission between the photonic die 100, the electrical die 600, and the processor die 700 can be achieved.

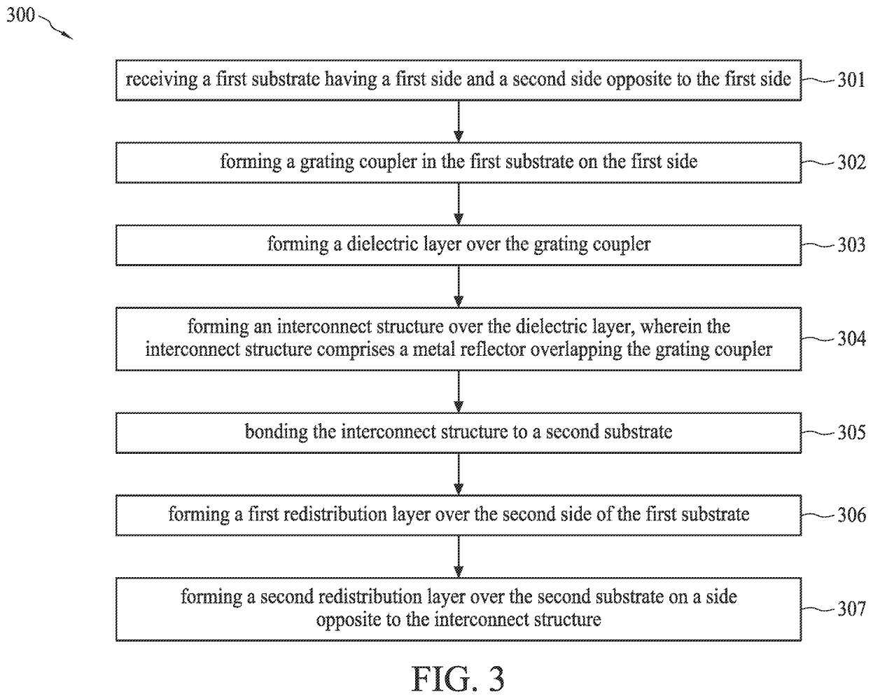

FIG. 3 illustrates an example flow chart of a method 300 for making a photonic die 400 according to some embodiments of the present disclosure. The method 300 includes a number of operations (301, 302, and 303 to 307). The method 300 will be further described according to one or more embodiments. It should be noted that the operations of the method 300 may be rearranged or otherwise modified within the scope of the various aspects. It should further be noted that additional processes may be provided before, during, and after the method 300, and that some other processes may be briefly described herein. Thus, other implementations are possible within the scope of the various aspects described herein.

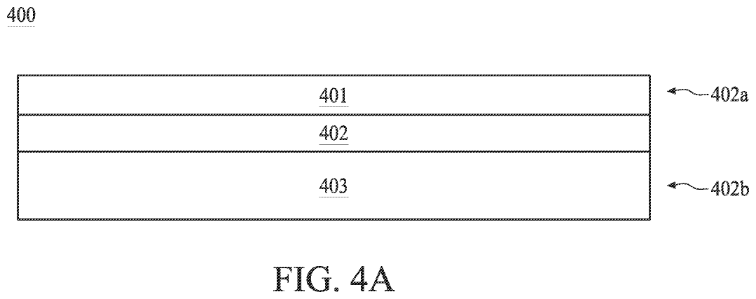

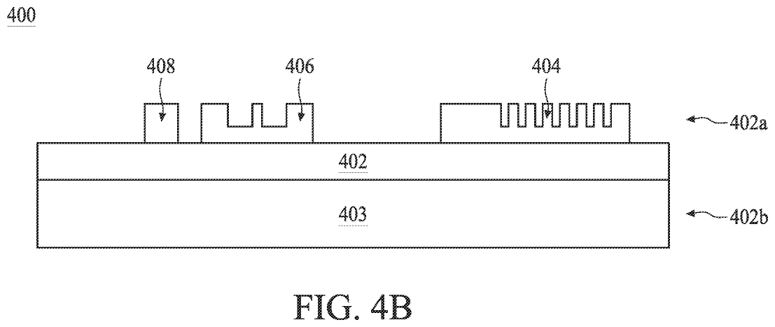

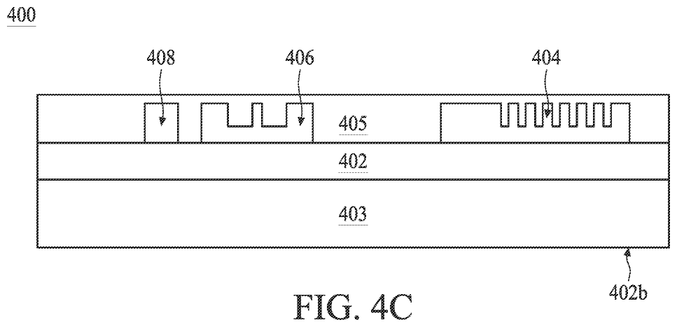

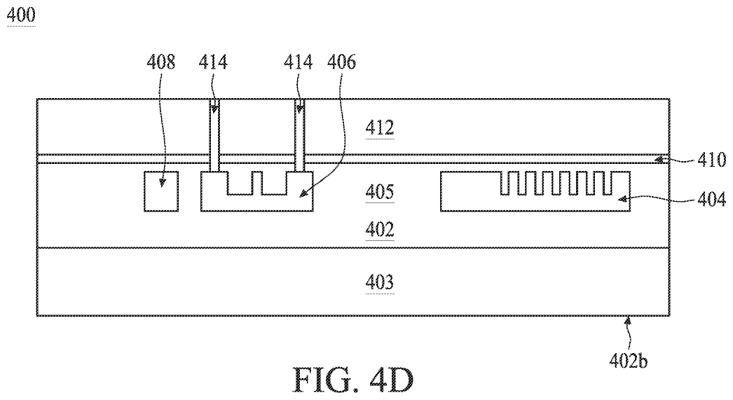

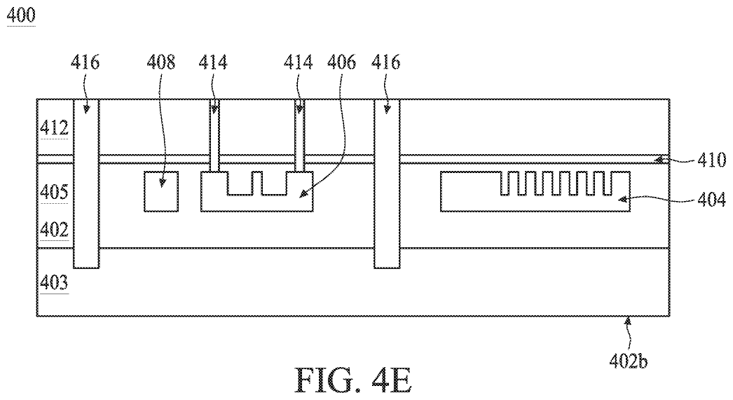

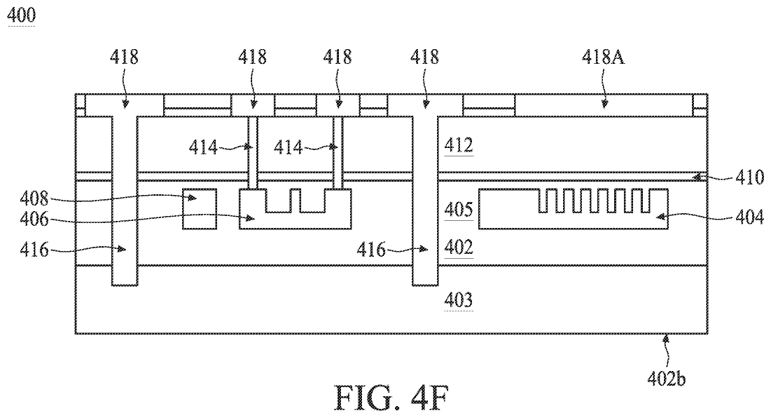

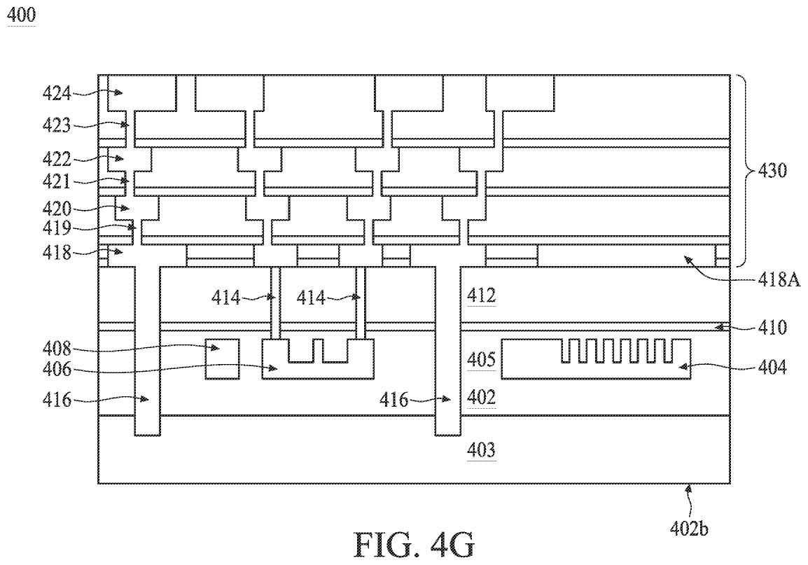

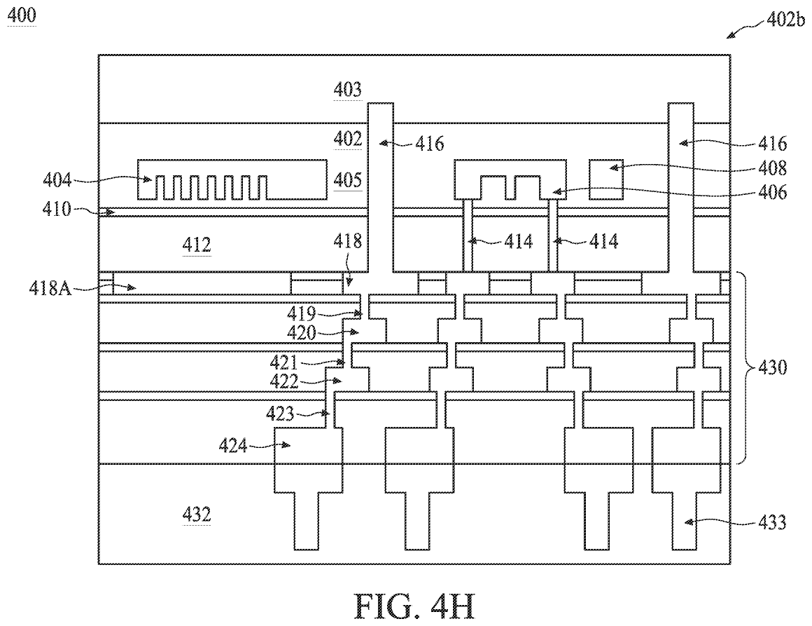

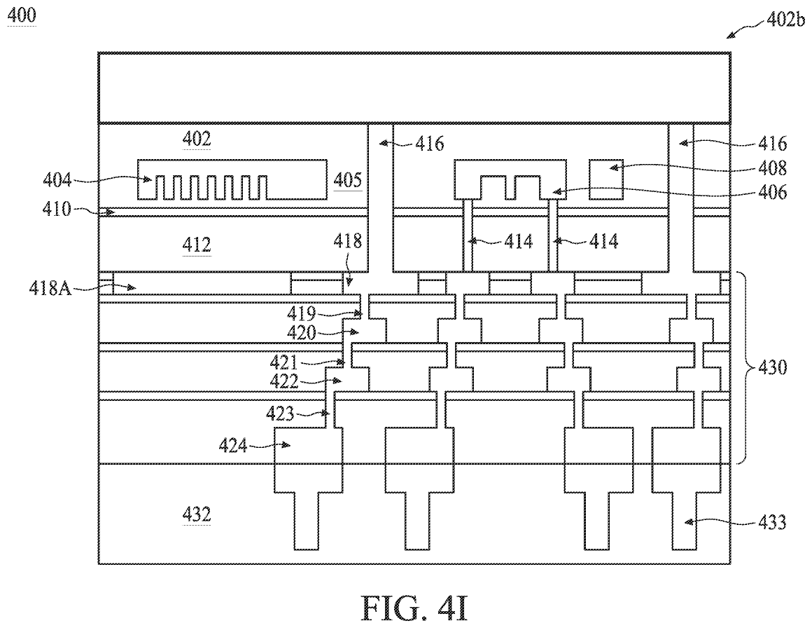

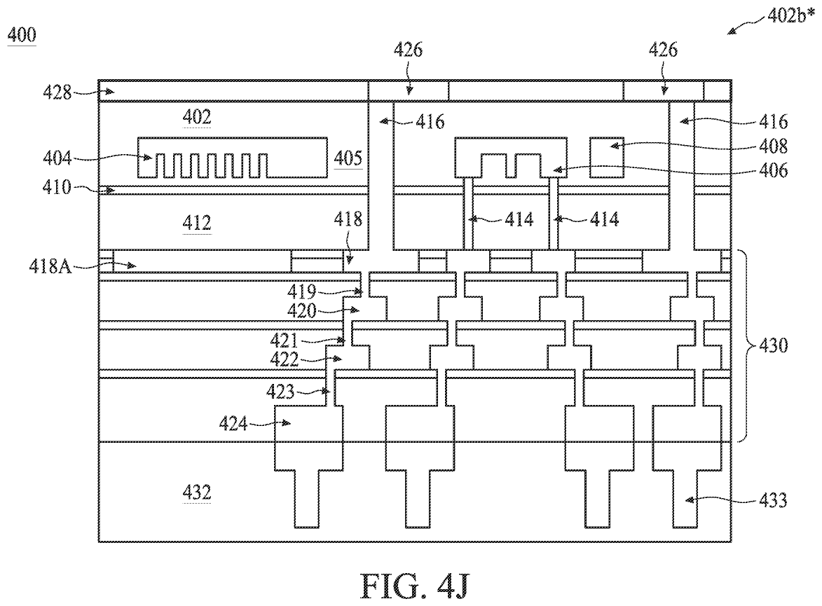

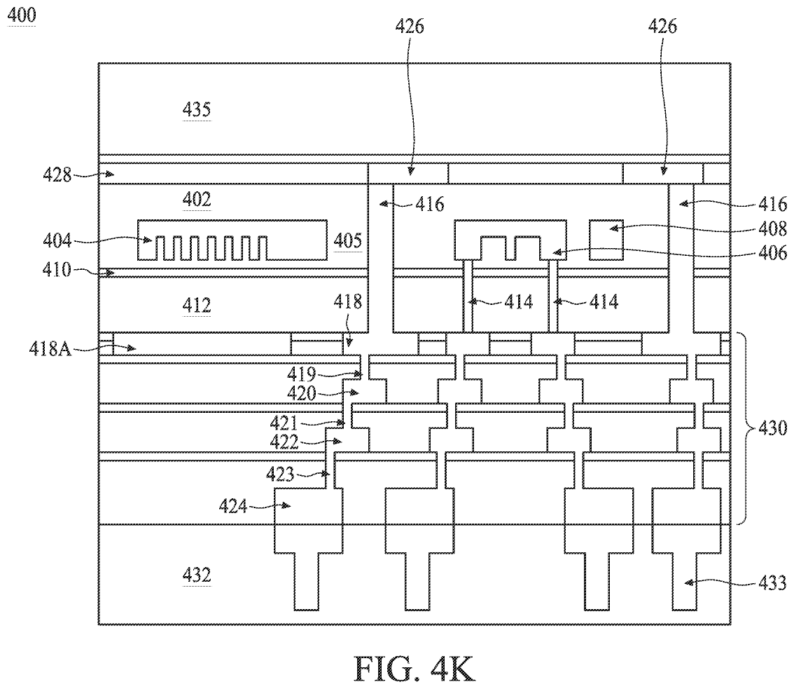

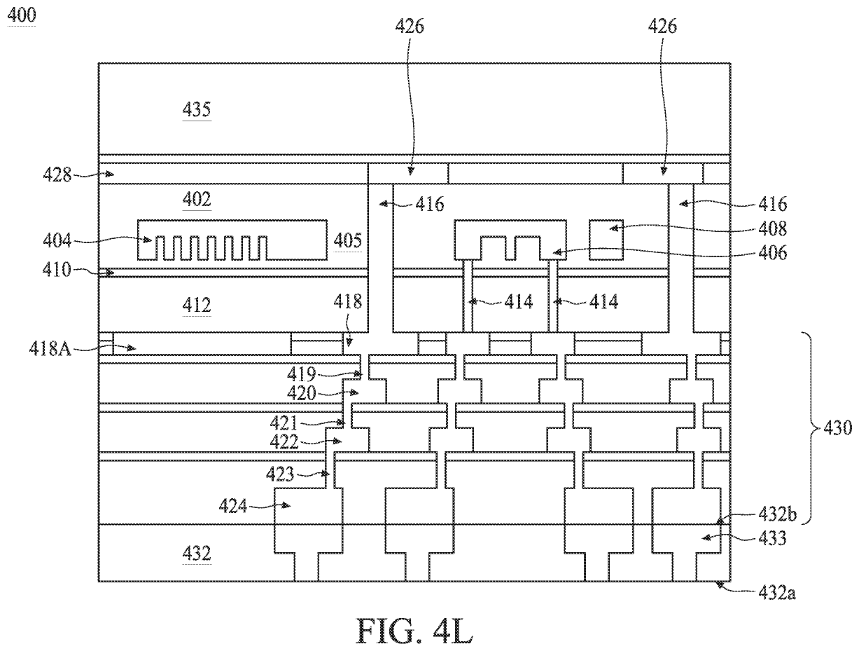

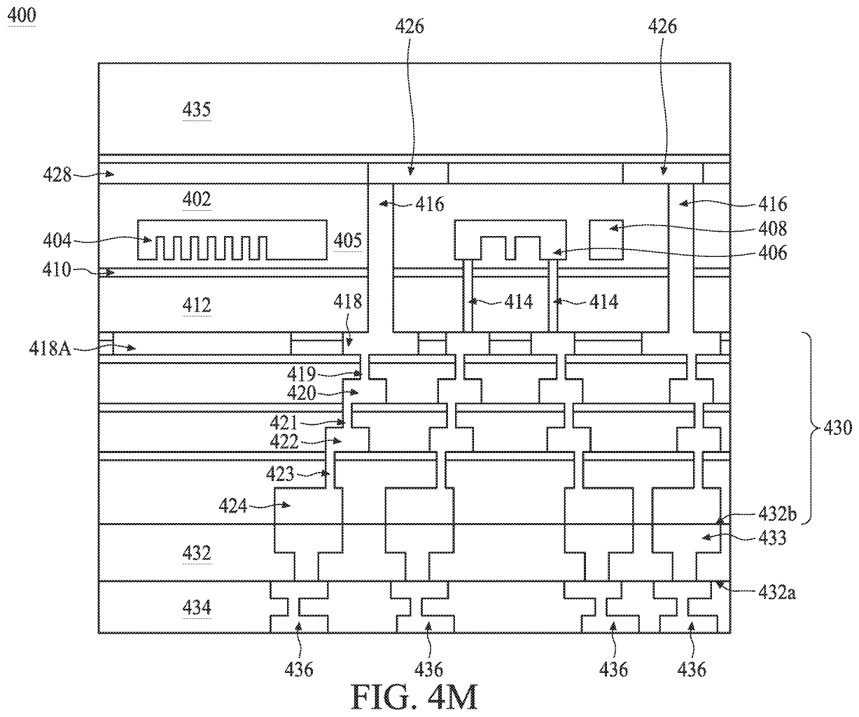

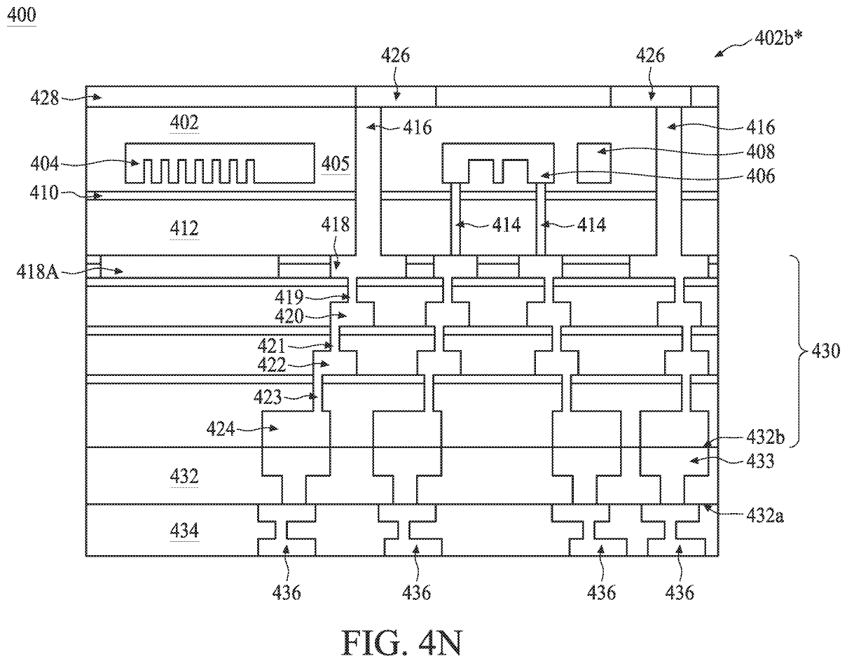

Referring to FIGS. 4A to 4N, which are schematic drawings illustrating a photonic die 400 at various fabrication stages according to aspects of the present disclosure in one or more embodiments. FIGS. 4A to 4M illustrate schematic drawings respectively of intermediate stages in the manufacturing of the photonic die 400, in accordance with some embodiments. FIG. 4N illustrates a schematic drawing of the photonic die 400 according to some embodiments. It should be noted that same elements in FIGS. 4A to 4N are indicated by the same numerals, and may include a same material. In some embodiments, the photonic die 400 can be provided as shown in FIGS. 4A to 4N.

Referring to FIG. 4A, in operation 301, a substrate is received. The substrate can be a silicon-on-insulator (SOI) substrate, and the SOI substrate includes a silicon substrate 403, a buried oxide (BOX) layer 402 over the silicon substrate 403, and a silicon layer 401 over the BOX layer 402. The SOI substrate includes a first surface (front side) 402a and a second surface (back side) 402b opposite to the first surface 402a.

Referring to FIG. 4B, in operation 302, a grating coupler 404 is formed in the silicon layer 401 on the first surface 402a of the SOI substrate. In some embodiments, operations for forming deep trench isolation and shallow trench isolation can be performed, thereby forming the grating coupler 404. In some embodiments, a modulator 406 and a strip 408 are also formed beside the grating coupler 404. As shown in FIG. 4B, the grating coupler 404, the modulator 406 and the strip 408 are separated from each other. In some embodiments, an implant process is performed on the modulator 406. The modulator 406 is doped with a p-type or an n-type dopant. A resist protective oxide (RPO) formation to protect the modulator 406 during a silicidation process.

In some embodiments, the RPO formation is a protection method such as, during the fabrication of a semiconductor device, parts of the device need to be protected while some other parts are processed. When, for example, memory and logic devices are fabricated on the same chip, electrical contacts on the logic part are made using the silicide (self-aligned silicide) process. As an exemplary example, to enable the selective silicidation of the logic side components, the memory part of the chip is protected by RPO and masked with a resist mask. The RPO film is then etched in the exposed areas of the chip. RPO etching process is critical, depending upon the application since other oxide films in the unmasked areas of the chip get attacked as well. When wet etching is used, the process will produce undercut profiles near the edge of the resist mask, resulting in poor dimensional control and resist mask peeling and mask lift-off.

Referring to FIG. 4C, in some embodiments, a dielectric material 405 is formed over the grating coupler 404, the modulator 406 and the strip 408. In one embodiment, the dielectric material 405 may be a material including silicon oxide, and/or other applicable dielectric materials. In some embodiments, a thickness of the dielectric material 405 is about 100 angstrom (Å), but the disclosure is not limited thereto. In some embodiments, a planarization process such as a CMP may be performed to remove the excess portions of the dielectric material 405.

Referring to FIG. 4D, in some embodiments, an etch stop layer such as a contact etch stop layer (CESL) 410 is blanket deposited over the dielectric material 405 by CVD, PVD, ALD or other applicable deposition. In one embodiment, the CESL 410 may include a material, such as, a dielectric material, such as, silicon nitride, silicon oxide, silicon oxynitride, or the like.

Still referring to FIG. 4D, in operation 303, a dielectric layer 412 is formed over the CESL 410. In one embodiment, the dielectric layer 412 may be an inter-level dielectric (ILD, also known as pre-metal dielectric) material. In some embodiments, the ILD material includes multilayers made of multiple dielectric materials, such as silicon oxide, silicon nitride, silicon oxynitride, TEOS, PSG, BPSG, low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the ILD material may be formed by CVD, PVD, ALD, spin-on coating, or other applicable processes. In some embodiments, a thickness of the dielectric layer 412 is within a range from about 5,000 Å to 10,000 Å, but the disclosure is not limited thereto.

Still referring to FIG. 4D, a contact plug 414 is formed over the modulator 406. In some embodiments, an etch process is perform to form an opening through the dielectric layer 412, the CESL 410, and a portion of the dielectric material 405. The modulator 406 is exposed from the opening. In some embodiment, a metal material such as copper or tungsten is filled in the opening to from the contact plug 414. A planarization process such as a CMP process is performed to remove the excess portions of the dielectric layer 412 and the contact plug 414.

Referring to FIG. 4E, a through substrate via (TSV) structure 416 is formed in the dielectric layer 412 and the SOI substrate. In some embodiments, an etch process is perform to form a via opening through the dielectric layer 412, the CESL 410, the dielectric material 405, the BOX layer 402, and a portion of the silicon substrate 403. In some embodiments, a depth of the via opening in the silicon substrate 403 is within a range from about 10 μm to about 50 μm, but the disclosure is not limited thereto. In some embodiments, the via opening is then filled by a metal material (such as copper). A planarization process such as a CMP process is then performed to remove the excess portions of the metal material, thereby forming a TSV structure 416, as shown in FIG. 4E.

Referring to FIGS. 4F and 4G, in operation 304, a first metallization layer 418 of an interconnect structure 430 is formed over the dielectric layer 412. In some embodiments, the first metallization layer 418 of the interconnect structure 430 comprises a metal reflector 418A. In some embodiments, the metal reflector 418A overlaps the grating coupler 404. In some embodiments, the metal reflector 418A is formed during the same process of forming the first metallization layer 418 of the interconnect structure 430. There is no extra process for forming the metal reflector 418A. In some embodiments, one part of the first metallization layer 418 is electrically connected to the modulator 406 via the contact plug 414. In some embodiments, another part of the first metallization layer 418 is directly electrically connected to the TSV structure 416. In some embodiments, the metal reflector 418A is electrically separated from the first metallization layer 418 of the interconnect structure 430. In some embodiments, a cross-sectional length of the metal reflector 418A is larger than a cross-sectional length of the grating coupler 104, for example, larger than about 1 micrometers (μm), but the disclosure is not limited thereto.

Referring to FIG. 4G, the interconnect structure 430 includes a plurality of metallization layers 418, 420, 422 and 424 and a plurality of inter-level via connectors 419, 421 and 423. In some embodiments, the plurality of metallization layers 418, 420, 422 and 424 and the plurality of inter-level via connectors 419, 421 and 423 are embedded in an inter-metal dielectric (IMD) material. In some embodiments, the metallization layers 418, 420, 422 and 424 and the inter-level via connectors 419, 421 and 423 are comprised of metallic material such as copper, aluminum, or alloys thereof, using known techniques such as damascene, dual damascene, or subtractive metal etching. Although the exemplary embodiments described herein depict five metal layers, this is merely illustrative and it should be understood that the interconnect structure 430 may alternatively be formed with more or fewer metal layers, depending on the application. The plurality of inter-level via connectors 419, 421 and 423 provide interconnections between the metallization layers 418, 420, 422 and 424.

In some embodiments, the 1 MB material between the interconnect structure 430 includes multilayers made of multiple dielectric materials, such as silicon oxide, silicon nitride, silicon oxynitride, TEOS, PSG, BPSG, low-k dielectric material, and/or other applicable dielectric materials. Examples of low-k dielectric materials include, but are not limited to, FSG, carbon doped silicon oxide, amorphous fluorinated carbon, parylene, BCB, or polyimide. In some embodiments, the 1 MB material may be formed by CVD, PVD, ALD, spin-on coating, or other applicable processes.

Referring to FIG. 4H, flip the SOI substrate. Next, in operation 305, a substrate 432, such as a carrier wafer, is bonded to the interconnect structure 430 by direct bonding (for example, Cu-to-Cu and Ox-to-Ox). In some embodiments, the substrate 432 may have one or more TSVs 433 formed in the substrate 432. In some embodiments, a thickness of the substrate 432 is with a range from about 100 μm to about 400 but the disclosure is not limited thereto. The substrate 432 comprises, for example, silicon based materials, such as glass or silicon oxide, or other materials, such as aluminum oxide, combinations of any of these materials, or the like. Referring to FIG. 4I, the silicon substrate 403 is removed from the back side 402b of the photonic die 400, for example, by an etching process.

Referring to FIG. 4J, in operation 306, a first redistribution layer 428 is formed over the back side 402b* of the photonic die 400. In some embodiments, the first redistribution layer 428 includes first RDL lines 426 electrically coupled with the interconnect structure 130 via the TSV structure 416. In some embodiments, the first redistribution layer 428 is used for the connection with other IC, for example, an EIC.

Referring to FIG. 4K, a handling wafer 435 is bonded to the first redistribution layer 428 temporarily, for example, by adhesive. The handling wafer 435 is to increase the thickness of the photonic die 400 to prevent the cracking during the following processes. In some embodiments, a thickness of the handling wafer 435 is with a range from about 100 μm to about 400 μm, but the disclosure is not limited thereto. Referring to FIG. 4L, the substrate 432 is thinned to expose the TSVs 433 in the substrate 432 for the subsequence process.

Referring to FIG. 4M, in operation 307, a second redistribution layer 434 is formed on the first side 432a of the substrate 432. The first side 432a of the substrate 432 is opposite to a second side 432b facing the interconnect structure 430. In some embodiments, the TSVs 433 of the substrate 432 is electrically connected with the 436. The second redistribution layer 434 includes second redistribution lines 436 electrically coupled with the TSVs 433 of the substrate 432. Referring to FIG. 4N, the handling wafer 435 is then stripped from the back side 402b* of the photonic die 400, for example, by heating up to a temperature of about 200° C. The photonic die 400 formed in FIG. 4N can be ready to integrate with other semiconductor devices.

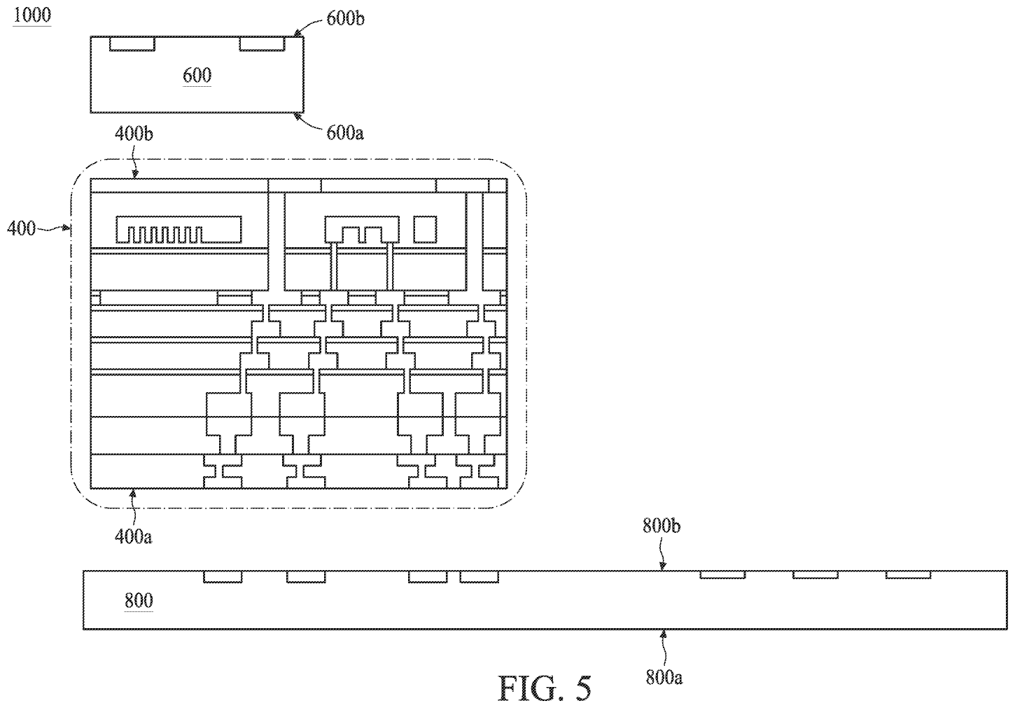

FIG. 5 illustrates an example exploded view of a semiconductor package 1000 according to some embodiments of the present disclosure. In some embodiments, a package substrate 800 may integrate several devices, such as an optical device (e.g., photonic die 400) which may be electrically coupled to an electrical device (e.g., electrical die 600), a processor die, an optical fiber, a package substrate, or other devices. In some embodiments, the semiconductor package 1000 may include the electrical die 600 with a first side 600a and a second side 600b, the photonic die 400 with a first side 400a and a second 400b, and the package substrate 800 with a first side 800a and a second side 800b.

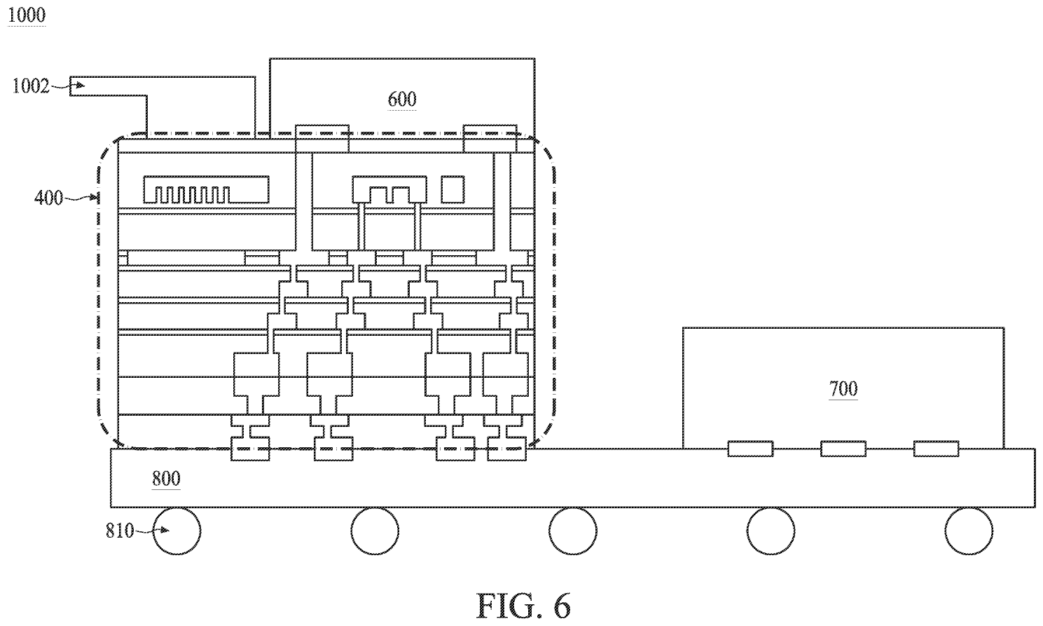

FIG. 6 illustrates an example cross-sectional view of the semiconductor package 1000 according to some embodiments of the present disclosure. As mentioned above, the first redistribution layer 428 is used for the connection with the electrical die 600. The electrical signals may be transmitted between the photonic die 400 and the electrical die 600. With the metal reflector 418A underlying the grating coupler 404 of the photonic die 400, the photonic die 400 can have a significantly improved light coupling efficiency. Light coupling efficiency may be enhanced by the metal reflector 418A to reflect the light and constructively interfere with the light coupled between the optical fiber 1002 and the grating coupler 404. Further, with the first RDL lines 426 electrically coupled with the photonic die 400, the signals between the photonic die 400 and the electrical die 600 can be exchanged. Also, with the package substrate 800, electrically coupled with the photonic die 400 and a processor die 700, the signals can be communicated through the photonic die 400, the electrical die 600, and the processor die 700. As such, an electrical transmission between the optical device, electrical device and the host device can be achieved. Accordingly, the metal reflector 418A may effectively improve the electrical transmission in the semiconductor package 1000, and also increase high-performance transmission in the semiconductor package 1000.

In some embodiments, the present disclosure provides a low cost, and production-friendly, a high efficiency photonic die and a method to combine a grating coupler and a metal reflector. With the metal reflector underlying the grating coupler of the photonic die, the photonic die can have a significantly improved light coupling efficiency. Light coupling efficiency may be enhanced by the metal reflector to reflect the light and constructively interfere with the light coupled between the optical fiber and the grating coupler. Further, the signals between the photonic die, the electrical die, and the processor die can be exchanged by integrated in a package substrate. As such, an electrical transmission between the optical device, electrical device and the host device can be achieved. Accordingly, the metal reflector may effectively improve the electrical transmission in the semiconductor package, and also increase high-performance transmission in the semiconductor package.

As described in greater detail above, some implementations described herein provide a photonic semiconductor structure including a substrate having a first side and a second side opposite to each other, a first redistribution layer disposed on the first side, an interconnect structure disposed on the second side of the substrate, a metal reflector disposed in the interconnect structure, a dielectric layer disposed over the interconnect structure, and a grating coupler disposed in the dielectric layer and overlapping the metal reflector.

As described in greater detail above, some implementations described herein provide a package of semiconductor structures including a substrate having a first side and a second side opposite to the first side, a photonic die disposed over the second side of the substrate and electrically coupled to the substrate, and an electrical die disposed over the photonic die and electrically connected to the photonic die. In some embodiments, the photonic die includes a die substrate, an interconnect structure disposed over the die substrate, a metal reflector disposed in the interconnect structure, a dielectric layer disposed over the interconnect structure, and a grating coupler disposed in the dielectric layer and overlapping the metal reflector.

As described in greater detail above, some implementations described herein provide a method of manufacturing a semiconductor structure including receiving a first substrate having a first side and a second side opposite to the first side, forming a grating coupler in the first substrate on the first side, forming a dielectric layer over the grating coupler, forming an interconnect structure over the dielectric layer, bonding the interconnect structure to a second substrate, forming a first redistribution layer over the second side of the first substrate, and forming a second redistribution layer over the second substrate on a side opposite to the interconnect structure. In some embodiments, the interconnect structure includes a metal reflector overlapping the grating coupler.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photonic semiconductor structure, comprising:
a substrate having a first side and a second side opposite to each other;
a first redistribution layer disposed on the first side;
an interconnect structure disposed on the second side of the substrate;
a metal reflector disposed in the interconnect structure;
a dielectric layer disposed over the interconnect structure; and
a grating coupler disposed in the dielectric layer and overlapping the metal reflector.

2. The photonic semiconductor structure of claim 1, wherein a cross-sectional length of the metal reflector is larger than a cross-sectional length of the grating coupler.

3. The photonic semiconductor structure of claim 1, wherein the interconnect structure further comprises a plurality of metallization layers and a plurality of inter-level via connectors.

4. The photonic semiconductor structure of claim 3, wherein the metal reflector is disposed at one of layers of the plurality of metallization layers.

5. The photonic semiconductor structure of claim 4, wherein the metal reflector is disposed at a topmost layer of the plurality of metallization layers.

6. The photonic semiconductor structure of claim 3, further comprising:
a second redistribution layer disposed over dielectric layer; and
at least one through substrate via penetrating the dielectric layer and electrically coupling one of the metallization layers of the interconnect structure with the second redistribution layer.

7. The photonic semiconductor structure of claim 3, further comprising:
a modulator disposed in the dielectric layer; and
a connecting structure penetrating the dielectric layer and electrically coupling one of the metallization layers of the interconnect structure with the modulator.

8. The photonic semiconductor structure of claim 1, further comprising a plurality of connecting structures disposed in the substrate and electrically coupling the first redistribution layer to the interconnect structure.

9. The photonic semiconductor structure of claim 1, wherein the metal reflector is electrically separated from the interconnect structure.

10. A package of semiconductor structures, comprising:
a substrate having a first side and a second side opposite to the first side;
a photonic die disposed over the second side of the substrate and electrically coupled to the substrate, wherein the photonic die comprises:
a die substrate;
an interconnect structure disposed over the die substrate;
a metal reflector disposed in the interconnect structure;
a dielectric layer disposed over the interconnect structure; and
a grating coupler disposed in the dielectric layer and overlapping the metal reflector; and
an electrical die disposed over the photonic die and electrically connected to the photonic die.

11. The package of claim 10, further comprising a processor die disposed over the second side of the substrate and electrically coupled to the substrate.

12. The package of claim 10, further comprising an optical fiber disposed over and coupled to the photonic die.

13. The package of claim 12, wherein the optical fiber and the electrical die are disposed over a same surface of the photonic die.

14. The package of claim 12, wherein the optical fiber overlaps the grating coupler of the photonic die.

15. The package of claim 10, further comprising a plurality of conductors disposed on the first side of the substrate.

16. A method of manufacturing a semiconductor structure, comprising:
receiving a first substrate having a first side and a second side opposite to the first side;
forming a grating coupler in the first substrate on the first side;
forming a dielectric layer over the grating coupler;
forming an interconnect structure over the dielectric layer, wherein the interconnect structure comprises a metal reflector overlapping the grating coupler;
bonding the interconnect structure to a second substrate;
forming a first redistribution layer over the second side of the first substrate; and
forming a second redistribution layer on the second substrate on a side opposite to the interconnect structure.

17. The method of claim 16, wherein the metal reflector is disposed at a bottommost layer of the interconnect structure.

18. The method of claim 16, further comprising thinning the first substrate prior to the forming of the first redistribution layer.

19. The method of claim 16, further comprising performing an ion implantation to form a modulator in the first substrate, wherein the modulator is separated from the grating coupler.

20. The method of claim 16, further comprising thinning the second substrate prior to the forming of the second redistribution layer.
